(19) United States
(12) Patent Application Publication
(10) Pub. No.: US 2026/0245636 A1
(43) Pub. Date: Aug. 20, 2026

(54) MEMORY DEVICE AND METHOD FOR OPERATING THE SAME

(71) Applicant: SK hynix Inc., Icheon-si Gyeonggi-do (KR)

(72) Inventor: Seung Jun LEE, Icheon-si Gyeonggi-do (KR)

(73) Assignee: SK hynix Inc., Icheon-si Gyeonggi-do (KR)

(21) Appl. No.: 19/390,042

(22) Filed: Nov. 14, 2025

(30) Foreign Application Priority Data
Feb. 14, 2025 (KR) 10-2025-0019535

(51) Int. Cl. G11C 16/30; G11C 5/14; G11C 16/08

(52) U.S. Cl. CPC G11C 16/30; G11C 5/147; G11C 16/08

(57) ABSTRACT

A memory device includes a plurality of word lines connected to a plurality of memory cells. The memory device also includes a peripheral circuit configured to sequentially perform a pass voltage application operation, a sensing voltage application operation, and an equalizing voltage application operation on the plurality of word lines. The peripheral circuit is configured to provide to a selected word line, during the equalizing voltage application operation, an electric charge of an unselected neighboring word line adjacent to the selected word line.

### CROSS-REFERENCE TO RELATED APPLICATION

The present application claims priority under 35 U.S.C. § 119(a) to Korean patent application number 10-2025-0019535 filed on February 14, 2025, in the Korean Intellectual Property Office, the entire contents of which application is incorporated herein by reference.

### BACKGROUND

### Technical Field

Various embodiments of the present disclosure generally relate to an electronic device, and more particularly, to a memory device and a method for operating the same.

### Related Art

Memory devices consist of an array of memory cells that store data and a peripheral circuit that drives the memory cells. The peripheral circuit generates various voltages used for memory operations, and performs a program operation, a read operation, and an erase operation under the control of control logic.

A read operation is an operation of applying a read voltage to a selected memory cell and determining an on-cell/off-cell to read data. In general, a read operation includes a pass voltage application process, a sensing voltage application process, and an equalizing voltage application process. In the equalizing voltage application process, a voltage of a selected word line and a voltage of unselected word lines are adjusted to a target level.

In the equalizing voltage application process, the voltage of the unselected word lines may be dropped and the voltage of the selected word line may be increased by applying an equalizing voltage. A voltage change of the selected word line in the equalizing voltage application process may affect a voltage of neighboring word lines. In an unselected word line which neighbors the selected word line among the unselected word lines, a disturbance phenomenon in which the neighboring unselected word line overshoots in the equalizing voltage application process may occur.

That is, in the equalizing voltage application process, the reliability of the memory device may be degraded due to the disturbance phenomenon between word lines which are adjacent to each other.

### SUMMARY

According to an embodiment of the present disclosure, a memory device may include: a plurality of word lines connected to a plurality of memory cells; a peripheral circuit configured to sequentially perform a precharge operation, a read operation, and an equalizing operation on the plurality of word lines; and control logic configured to control the peripheral circuit. The peripheral circuit is configured to provide to a selected word line, during the equalizing voltage application operation, an electric charge of an unselected neighboring word line located close to the selected word line.

According to an embodiment of the present disclosure, a method of operating a memory device may include: applying a pass voltage to a plurality of word lines connected to a plurality of memory cells; applying a sensing voltage to the plurality of word lines; and applying an equalizing voltage to the plurality of word lines. In applying the equalizing voltage, an electric charge of an unselected neighboring word line adjacent to a selected word line is provided to the selected word line.

### BRIEF DESCRIPTION OF THE DRAWINGS

FIG. 1 is a diagram illustrating a memory device according to an embodiment of the present disclosure;

FIG. 2 is a diagram illustrating a memory block shown in FIG. 1;

FIG. 3 is a diagram illustrating in detail configurations of a voltage generator, a row decoder, and control logic shown in FIG. 1;

FIG. 4 is a diagram illustrating a voltage change of neighboring word lines due to a voltage change of a selected word line;

FIG. 5A is a diagram illustrating a read operation of a memory device according to an embodiment of the present disclosure;

FIG. 5B is a detailed view of an equalizing voltage application period shown in FIG. 5A;

FIG. 6A is a circuit diagram illustrating an operation of a circuit of the memory device which corresponds to portions represented by dotted lines shown in FIG. 5B during the equalizing voltage application period;

FIG. 6B is a circuit diagram illustrating an operation of the circuit of the memory device which corresponds to portions represented by solid lines shown in FIG. 5B during the equalizing voltage application period;

FIG. 7 is a circuit diagram illustrating an operation of a circuit of a memory device during an equalizing voltage application period according to a first embodiment of the present disclosure;

FIG. 8 is a circuit diagram illustrating an operation of a circuit of a memory device during an equalizing voltage application period according to a second embodiment of the present disclosure;

FIG. 9 is a circuit diagram illustrating an operation of a circuit of a memory device during an equalizing voltage application period according to a third embodiment of the present disclosure;

FIG. 10 is a circuit diagram illustrating an operation of a circuit of a memory device during an equalizing voltage application period according to a fourth embodiment of the present disclosure;

FIG. 11 is a circuit diagram illustrating an operation of a circuit of a memory device during an equalizing voltage application period according to a fifth embodiment of the present disclosure;

FIG. 12 is a diagram illustrating a memory card system to which a memory device according to an embodiment of the present disclosure is applied; and

FIG. 13 is a diagram illustrating a Solid-State Drive (SSD) system to which a memory device according to an embodiment of the present disclosure is applied.

### DETAILED DESCRIPTION

Specific structural or functional descriptions disclosed herein are merely illustrative for the purpose of describing embodiments according to the concept of the present disclosure. Embodiments according to the concept of the present disclosure can be implemented in various forms and replaced with other equivalent embodiments, and they should not be construed as being limited to the specific embodiments set forth herein.

It will be understood that, although the terms “first,” “second,” etc. may be used herein to describe various elements, these elements are not limited by these terms. These terms are used for distinguishing one element from another element and not to suggest a number or order of elements.

Various embodiments are directed to a memory device and a method of operating the same, which may improve the reliability of the memory device.

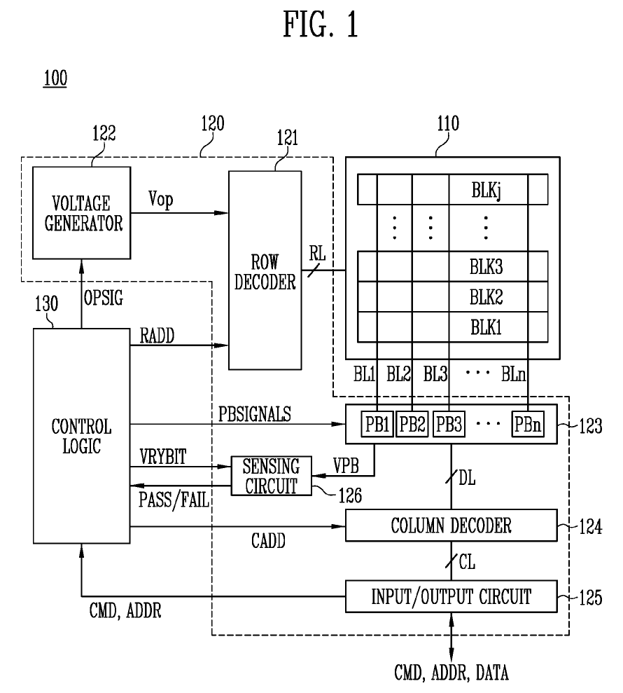

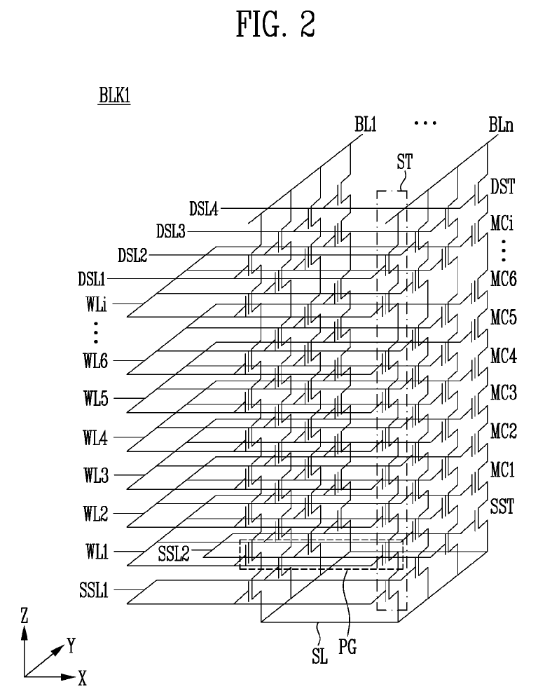

FIG. 1 is a diagram illustrating a memory device 100 according to an embodiment of the present disclosure, and FIG. 2 is a diagram illustrating a memory block shown in FIG. 1.

Referring to FIGS. 1 and 2, the memory device 100 may include a memory cell array 110, a peripheral circuit 120, and control logic 130.

The memory cell array 110 includes first to j-th memory blocks BLK1 to BLKj. The first to j-th memory blocks BLK1 to BLKj are connected to a row decoder 121 through row lines RL. The first to j-th memory blocks BLK1 to BLKj may be connected to a page buffer group 123 through bit lines BL1 to BLn. Each of the first to j-th memory blocks BLK1 to BLKj includes a plurality of cell strings ST, and each of the plurality of cell strings ST includes a plurality of memory cells. In an embodiment, the plurality of memory cells are non-volatile memory cells. Memory cells connected to the same word line may be defined as a single page PG. Thus, one memory block may include a plurality of pages.

The first to j-th memory blocks BLK1 to BLKj may be configured the same as each other, and thus, a structure of a memory block is described in detail below, taking the first memory block BLK1 as an example.

Referring to FIG. 2, the first memory block BLK1 includes the cell strings ST connected between the first to n-th bit lines BL1 to BLn and a source line SL. Because the first to n-th bit lines BL1 to BLn extend in a Y direction and are arranged spaced apart from each other in an X direction, the cell strings ST may also be arranged spaced apart from each other in the X and Y directions. For example, the cell strings ST may be connected between the first bit line BL1 and the source line SL, and the cell strings ST may be arranged between the second bit line BL2 and the source line SL. In this way, the cell strings ST may be arranged between the n-th bit line BLn and the source line SL. The cell strings ST may extend in a Z direction.

To illustrate, for example, one of the cell strings ST connected to the n-th bit line BLn, the cell string ST may include a source select transistor SST, first to i-th memory cells MC1 to MCi, and a drain select transistor DST. Because FIG. 2 of the first memory block BLK1 is a diagram for schematically illustrating the structure of the memory block, the number of source select transistors SST, first to i-th memory cells MC1 to MCi, and drain select transistors DST included in the cell strings ST may be changed in different embodiments of a memory device.

Gates of the source select transistors SST included in different cell strings may be connected to a first or second source select line SSL1 or SSL2, gates of the first to i-th memory cells MC1 to MCi may be connected to first to i-th word lines WL1 to WLi, and each of gates of the drain select transistors DST may be connected to one of first to fourth drain select lines DSL1 to DSL4.

To describe the lines connected to the first memory block BLK1 in more detail, the source select transistors SST arranged in the X direction may be connected to the same source select line as each other, and the source select transistors SST arranged in the Y direction may be connected to source select lines separated from each other. For example, among the source select transistors SST arranged in the Y direction, one or more of the source select transistors SST may be connected to the first source select line SSL1, and the rest of the source select transistors SST may be connected to the second source select line SSL2. The second source select line SSL2 is a line separated from the first source select line SSL1. Thus, a voltage applied to the first source select line SSL1 may be the same as or different from a voltage applied to the second source select line SSL2.

Memory cells formed on the same level among the first to i-th memory cells MC1 to MCi may be connected to the same word line. For example, the first memory cells MC1 included in different cell strings ST may be connected in common to the first word line WL1, and the i-th memory cells MCi included in different cell strings ST may be connected in common to the i-th word line WLi. A group of memory cells included in different cell strings ST and connected to the same word line constitutes a page PG. Program and read operations may be performed in units of pages PG, and pre-program and erase operations may be performed in units of memory blocks. Operations performed in units of memory blocks may be performed on all pages included in a selected memory block.

The drain select transistors DST arranged in the Y direction may be connected to the first to fourth drain select lines DSL1 to DSL4 separated from each other. Specifically, the drain select transistors DST arranged in the X direction may be connected to the same drain select line as each other, and the drain select transistors DST arranged in the Y direction may be connected to the first to fourth drain select lines DSL1 to DSL4 separated from each other. Because the first to fourth drain select lines DSL1 to DSL4 are separated from each other, different voltages may be applied to the first to fourth drain select lines DSL1 to DSL4.

Referring to FIGS. 1 and 2, the row lines RL may include the source select lines SSL1 and SSL2, the plurality of word lines WL1 to WLi, and the drain select lines DSL1 to DSL4. The source select lines SSL1 and SSL2, the plurality of word lines WL1 to WLi, and the drain select lines DSL1 to DSL4 may be connected to each of the first to j-th memory blocks BLK1 to BLKj. Each of the bit lines BL1 to BLn may be connected to at least one cell string.

The memory cells included in the memory cell array 110 may be programmed using a Multi-Level Cell (MLC) method, a Triple-Level Cell (TLC) method, or a Quad-Level Cell (QLC) method depending on the number of bits of data stored. Each of the memory cells programmed using the MLC method may store two bits of data. Each of the memory cells programmed using the TLC method may store three bits of data. Each of the memory cells programmed using the QLC method may store four bits of data. Different methods may be used to program memory cells depending on a type of memory device. In addition to the methods described above, a method of programming five or more bits of data in one memory cell may be used.

The peripheral circuit 120 may be configured to perform a program operation, a read operation, or an erase operation on selected regions of the memory cell array 110 under the control of the control logic 130. For example, the peripheral circuit 120 may apply various operating voltages to the row lines RL and the first to n-th bit lines BL1 to BLn, or it may selectively discharge the row lines RL and the first to n-th bit lines BL1 to BLn under the control of the control logic 130.

The peripheral circuit 120 may include the row decoder 121, a voltage generator 122, the page buffer group 123, a column decoder 124, an input/output circuit 125, and a sensing circuit 126.

The row decoder 121 is connected to the memory cell array 110 through the row lines RL. The row lines RL may include at least one source select line, a plurality of word lines, and at least one drain select line. In an embodiment, the word lines may include normal word lines and dummy word lines.

The row decoder 121 is configured to decode a row address RADD received from the control logic 130. The row decoder 121 selects at least one of the memory blocks BLK1 to BLKj according to the decoded address. In addition, the row decoder 121 may transmit operating voltages Vop generated by the voltage generator 122 to the row lines RL of the selected memory block according to the decoded address.

For example, in a program operation, the row decoder 121 may apply a program voltage to a selected word line and a program pass voltage at a lower level than the program voltage to unselected word lines. In a program verify operation, the row decoder 121 may apply a verify voltage to the selected word line and a verify pass voltage at a higher level than the verify voltage to the unselected word lines. In a read operation, the row decoder 121 may apply a read voltage to the selected word line and a read pass voltage at a higher level than the read voltage to the unselected word lines.

An erase operation of the memory device 100 is performed in units of memory blocks. In the erase operation, the row decoder 121 may select one memory block according to the decoded address. In the erase operation, the row decoder 121 may apply a voltage of 0V or a ground voltage to word lines connected to the selected memory block, or it may cause the word lines to float.

The voltage generator 122 operates under the control of the control logic 130. The voltage generator 122 is configured to generate a plurality of voltages using an external power voltage supplied to the memory device 100. Specifically, the voltage generator 122 may generate the various operating voltages Vop used for performing program, read, and erase operations in response to an operation signal OPSIG generated in the control logic 130. For example, the voltage generator 122 may generate a program voltage, a verify voltage, a pass voltage, a read voltage, an erase voltage, and the like in response to the control of the control logic 130.

The page buffer group 123 includes first to n-th page buffers PB1 to PBn. The first to n-th page buffers PB1 to PBn are connected to the memory cell array 110 through the first to n-th bit lines BL1 to BLn. The first to n-th page buffers PB1 to PBn operate under the control of the control logic 130. Specifically, the first to n-th page buffers PB1 to PBn may operate in response to page buffer control signals PBSIGNALS. For example, the first to n-th page buffers PB1 to PBn may temporarily store data received through the first to n-th bit lines BL1 to BLn, or they may sense a voltage or current of the first to n-th bit lines BL1 to BLn during a read or verify operation.

Specifically, during a program operation, when a program voltage is applied to the selected word line, the first to n-th page buffers PB1 to PBn transmit data DATA received through the input/output circuit 125 to the selected memory cells through the first to n-th bit lines BL1 to BLn. The memory cells of the page selected according to the transmitted data DATA are programmed. In a program verify operation, the first to n-th page buffers PB1 to PBn sense the voltage or current received from the selected memory cells through the first to n-th bit lines BL1 to BLn to read page data.

In a read operation, the first to n-th page buffers PB1 to PBn read the data DATA from the memory cells of the selected page through the first to n-th bit lines BL1 to BLn, and they output the read data DATA to the input/output circuit 125 under the control of the column decoder 124.

In an erase operation, the first to n-th page buffers PB1 to PBn may float the first to n-th bit lines BL1 to BLn or apply the erase voltage to the first to n-th bit lines BL1 to BLn.

The column decoder 124 may transmit data between the input/output circuit 125 and the page buffer group 123 in response to a column address CADD. For example, the column decoder 124 may exchange data with the first to n-th page buffers PB1 to PBn through data lines DL, or it may exchange the data with the input/output circuit 125 through column lines CL.

The input/output circuit 125 may transmit a command CMD and an address ADDR received from a memory controller to the control logic 130, or it may exchange the data DATA with the column decoder 124.

The sensing circuit 126 may generate a reference current in response to an allowable bit VRYBIT signal during a read operation or a verify operation, and it may compare a sensing voltage VPB received from the page buffer group 123 with a reference voltage generated by the reference current to output a pass signal PASS or a fail signal FAIL.

The control logic 130 may output the operation signal OPSIG, the row address RADD, the page buffer control signals PBSIGNALS, and the allowable bit VRYBIT in response to the command CMD and the address ADDR to control the peripheral circuit 120. For example, the control logic 130 may control the read operation of the selected memory block in response to a sub-block read command and address. Further, the control logic 130 may control the erase operation of a selected sub-block included in the selected memory block in response to a sub-block erase command and address. In addition, the control logic 130 may determine whether the verify operation has been passed or failed in response to the pass or fail signal PASS or FAIL. The control logic 130 may be implemented as hardware, software, or a combination of hardware and software. For example, the control logic 130 may be a control logic circuit operating in accordance with an algorithm and/or a processor executing control logic code.

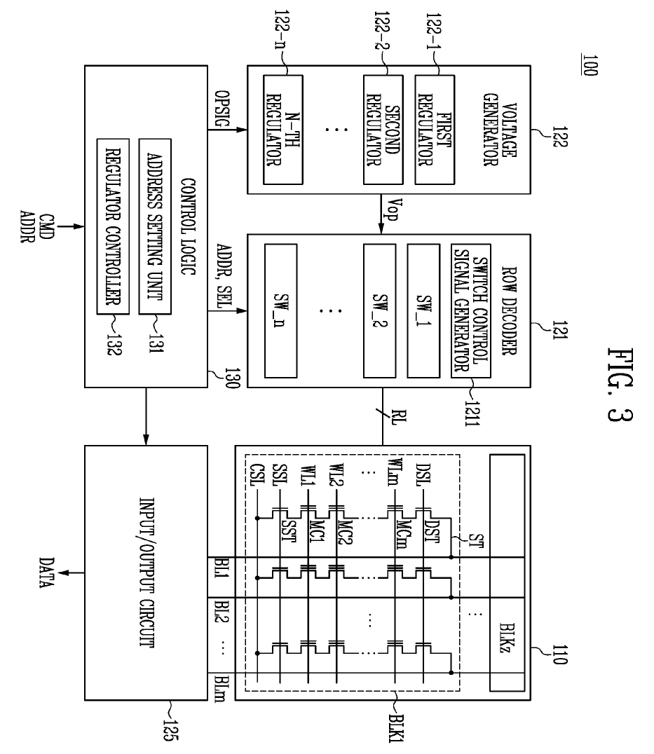

FIG. 3 is a diagram illustrating in detail configurations of the voltage generator 122, the row decoder 121, and the control logic 130 shown included in the memory device 100 of FIG. 1.

Referring to FIG. 3, the voltage generator 122 may include a plurality of regulators 122-1 to 122-n. Each of the plurality of regulators 122-1 to 122-n may generate a voltage.

The row decoder 121 includes a switch control signal generator 1211 and a plurality of switching circuits SW_1 to SW_n. The plurality of switching circuits SW_1 to SW_n may be connected to the plurality of regulators 122-1 to 122-n of the voltage generator 122.

The switch control signal generator 1211 may generate a switch control signal for controlling the plurality of switching circuits SW_1 to SW_n in response to a select signal SEL of the control logic 130.

The select signal SEL may include a signal for selecting, from among the plurality of switching circuits SW_1 to SW_n, switching circuits to be turned on and switching circuits to be turned off.

The plurality of switching circuits SW_1 to SW_n may be connected to one of a plurality of word lines WL1 to WLm (m is a natural number). In addition, the plurality of switching circuits SW_1 to SW_n may be connected to the plurality of regulators 122-1 to 122-n. Each of the plurality of switching circuits SW_1 to SW_n may connect one of the plurality of word lines WL1 to WLm to one of the plurality of regulators 122-1 to 122-n.

The control logic 130 may control the voltage generator 122, the row decoder 121, and the input/output circuit 125. The control logic 130 may operate in response to the command CMD transmitted from an external device. The control logic 130 may generate various signals based on the command CMD and the address ADDR to control peripheral circuits.

The control logic 130 includes an address setting unit 131 and a regulator controller 132.

The address setting unit 131 may set, based on an address of a selected word line WL_S selected in the read operation, addresses of neighboring word lines WL_N1 adjacent to the selected word line WL_S and addresses of non-neighboring word lines WL_N2 not adjacent to the selected word line WL_S among a plurality of unselected word lines WL_N. The neighboring word lines WL_N1 are word lines which are not selected during the read operation, and are located closest to the selected word line WL_S. The non-neighboring word lines WL_N2 are word lines which are not selected during the read operation and are not located close to the selected word line WL_S.

For example, when it is assumed that the selected word line WL_S is the i-th word line WLi (i is a natural number) of a specific memory block, addresses of the neighboring word lines WL_N1 may be set to addresses of the (i-1)-th word line WLi-1 and the (i+1)-th word line WLi+1.

Also, for example, when it is assumed that the selected word line WL_S is the first word line WL1 of a specific memory block, there is only the second word line WL2 which is adjacent to the selected word line WL_S. Therefore, an address of the neighboring word line WL_N1 may be set to an address of the second word line WL2.

Also, for example, when it is assumed that the selected word line WL_S is the n-th word line WLn, which is the last word line of a specific memory block, there is only the (n-1)-th word line WLn-1) which is adjacent to the n-th word line WLn. An address of the neighboring word line WL_N1 may be set to an address of the (n-1)-th word line WLn-1.

Unlike the above descriptions, the address setting unit 131 may set the addresses of the plurality of neighboring word lines WL_N1 adjacent to the selected word line WL_S based on the address of the selected word line WL_S selected during the read operation. That is, when c is a natural number and X is a natural number of 3 or more, the number of neighboring word lines WL_N1 may be set to 2c to Xc.

For example, when X is 2, when it is assumed that the selected word line WL_S is the i-th word line WLi of a specific memory block, addresses of the neighboring word lines WL_N1 may be set to addresses of the (i-1)-th word line WLi-1, the (i-2)-th word line WLi-2, the (i+1)-th word line WLi+1, and the (i+2)-th word line WLi+2.

Also, for example, when it is assumed that the selected word line WL_S is the first word line WL1 of a specific memory block, the second word line WL2 and the third word line WL3 constitute word lines adjacent to the selected word line WL_S. Therefore, addresses of the neighboring word lines WL_N1 may be set to addresses of the second word line WL2 and the third word line WL3.

Also, for example, when it is assumed that the selected word line WL_S is the n-th word line WLn, which is the last word line of a specific memory block, the (n-1)-th word line WLn-1 and the (n-2)-th word line WLn-2 constitute the neighboring word lines WL_N1 adjacent to the n-th word line WLn. Addresses of the neighboring word lines WL_N1 may be set to addresses of the (n-1)-th word line WLn-1 and the (n-2)-th word line WLn-2.

The address setting unit 131 sets the addresses of the non-neighboring word lines WL_N2 which are not adjacent to the selected word line WL_S among the plurality of unselected word lines WL_N, based on the address of the selected word line WL_S selected during the read operation. The non-neighboring word lines WL_N2 are word lines which are not selected during the read operation, and they exclude the selected word line WL_S and the neighboring word lines WL_N1. The non-neighboring word lines WL_N2 are word lines which are not located closest to the selected word line WL_S.

For example, when it is assumed that the selected word line WL_S is the first word line WL1 of a specific memory block, the neighboring word line WL_N1 adjacent to the selected word line WL_S is the second word line WL2. Accordingly, the third to n-th word lines WL3 to WLn constitute the non-neighboring word lines WL_N2.

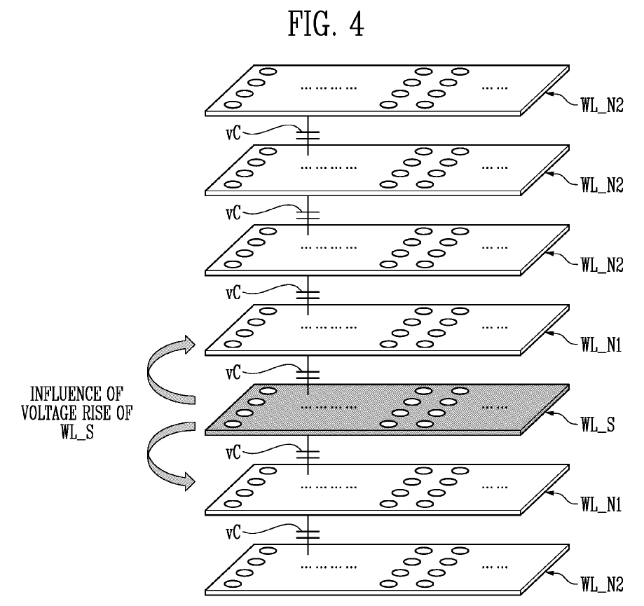

FIG. 4 is a diagram illustrating a voltage change of the neighboring word lines WL_N1 due to a voltage change of the selected word line WL_S.

Referring to FIG. 4, it may be seen that a virtual capacitor vC is formed between the selected word line WL_S and the neighboring word lines WL_N1, resulting in coupling, for example, capacitive coupling, therebetween. The voltage change of the selected word line WL_S may affect the voltage of the neighboring word lines WL_N1 by the virtual capacitor vC.

In FIG. 4, the virtual capacitor Vc is formed only between each pair of adjacent word lines. The virtual capacitor vC is not shown between the word line WL_S and the non-neighboring word line WL_N2 that are not adjacent to each other. However, the virtual capacitor vC may also be formed between the selected word line WL_S and the non-neighboring word line WL_N2.

When the virtual capacitor vC is formed between the selected word line WL_S and the neighboring word line WL_N1, the voltage change of the selected word line WL_S may affect the voltage of the neighboring word line WL_N1. Specifically, when the voltage of the selected word line WL_S rises, even when no separate voltage is applied to the neighboring word line WL_N1, the voltage of the neighboring word line WL_N1 may also rise under the influence of the voltage rise of the selected word line WL_S. Conversely, when the voltage of the selected word line WL_S drops, even when no separate voltage is applied to the neighboring word line WL_N1, the voltage of the neighboring word line WL_N1 may also drop under the influence of the voltage drop of the selected word line WL_S. The influence of the voltage change of the selected word line WL_S on the voltage of the non-neighboring word lines WL_N2 may be weak compared to the influence of the voltage change of the selected word line WL_S on the voltage of the neighboring word lines WL_N1. That is, the voltage change of the selected word line WL_S does not or only negligibly affects the voltage of the non-neighboring word lines WL_N2.

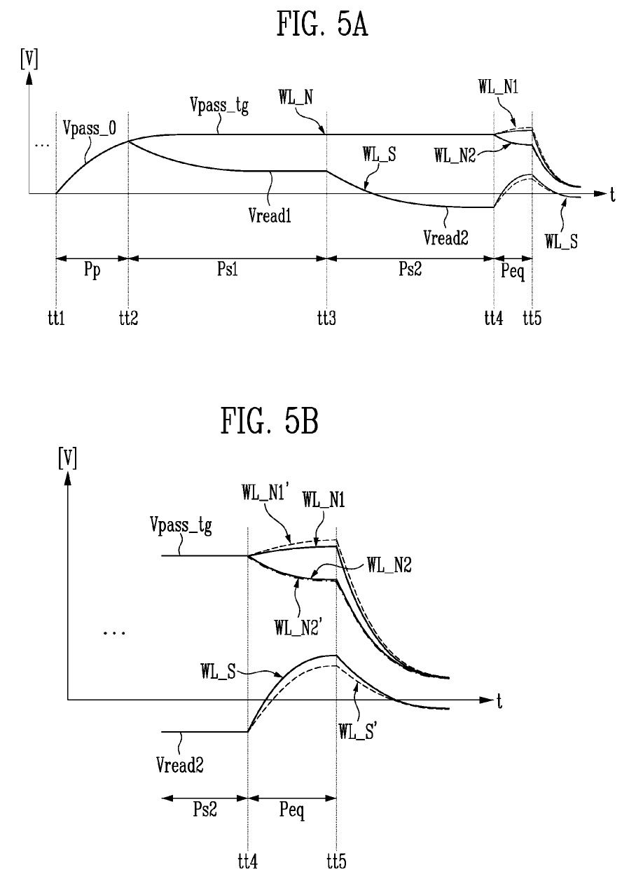

FIG. 5A is a diagram illustrating a read operation of a memory device according to an embodiment of the present disclosure, and FIG. 5B is a detailed view of an equalizing voltage application period Peq shown in FIG. 5A.

Referring to FIG. 5A, the read operation of the memory device according to an embodiment of the present disclosure includes a first pass voltage application operation in a pass voltage application period Pp, a first sensing voltage application operation in a first sensing voltage application period Ps1, a second sensing voltage application operation in a second sensing voltage application period Ps2, and an equalizing voltage application operation in the equalizing voltage application period Peq. The above-described operations are performed by the peripheral circuit 120 (of FIG. 1) under the control of the control logic 130 (of FIG. 1).

During the pass voltage application period Pp from a first time point tt1 to a second time point tt2, the control logic 130 (of FIG. 3) applies a first pass voltage Vpass_0 to the plurality of word lines. Specifically, the control logic 130 (of FIG. 3) applies the first pass voltage Vpass_0 to all of the selected word line WL_S, the neighboring word lines WL_N1, and the non-neighboring word lines WL_N2 in the pass voltage application period Pp. As the first pass voltage Vpass_0 is applied, the selected word line WL_S, the neighboring word lines WL_N1 and the non-neighboring word lines WL_N2 all have the same potential.

During the first sensing voltage application period Ps1 from the second time point tt2 to a third time point tt3, the control logic 130 (of FIG. 3) performs the first sensing voltage application operation on the plurality of word lines, and during the second sensing voltage application period Ps2 from the third time point to a fourth time point tt4, the control logic 130 (of FIG. 3) performs the second sensing voltage application operation on the plurality of word lines.

Specifically, the control logic 130 (of FIG. 3) applies a target pass voltage Vpass_tg to the unselected word lines WL_N during the first sensing voltage application period Ps1 and the second sensing voltage application period Ps2. Then, the control logic 130 (of FIG. 3) applies a first read voltage Vread1 to the selected word line WL_S during the first sensing voltage application period Ps1, and it applies a second read voltage Vread2 to the selected word line WL_S during the second sensing voltage application period Ps2. The unselected word lines WL_N include the neighboring word lines WL_N1 and the non-neighboring word lines WL_N2.

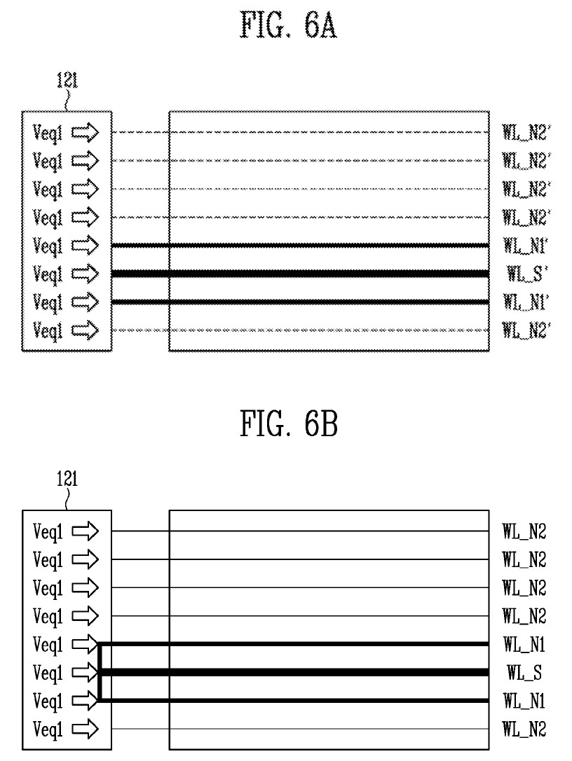

FIG. 6A is a circuit diagram illustrating an operation of a circuit of the memory device which corresponds to portions represented by dotted lines shown in FIG. 5B during the equalizing voltage application period Peq, and FIG. 6B is a circuit diagram illustrating an operation of the circuit of the memory device which corresponds to portions represented by solid lines shown in FIG. 5B during the equalizing voltage application period Peq.

Referring to FIGS. 5B and 6A, the portions represented by the dotted lines in the equalizing voltage application period Peq from the fourth time point tt4 to a fifth time point tt5 are described.

During the equalizing voltage application period Peq, a first equalizing voltage Veq1 is applied to a dotted selected word line WL_S’, dotted neighboring word lines WL_N1’, and dotted non-neighboring word lines WL_N2’. The magnitude of the first equalizing voltage Veq1 may be greater than the magnitude of a voltage of the dotted selected word line WL_S’, and it may be less than a voltage of each of the dotted neighboring word lines WL_N1’ and the dotted non-neighboring word lines WL_N2’ at the fourth time point tt4.

The dotted selected word line WL_S’ is a selected word line, the dotted neighboring word lines WL_N1’ are word lines located nearest to the dotted selected word line WL_S’, and the dotted non-neighboring word lines WL_N2’ are remaining word lines of a plurality of word lines in one memory block except for the dotted selected word line WL_S’ and the dotted neighboring word lines WL_N1’.

During the equalizing voltage application period Peq, when the first equalizing voltage Veq1 is applied to the dotted selected word line WL_S’, the voltage of the dotted selected word line WL_S’ may rise by the first equalizing voltage Veq1. The cause of the voltage rise of the dotted selected word line WL_S’ is the first equalizing voltage Veq1.

Due to the coupling between the dotted neighboring word lines WL_N1’ and the dotted selected word line WL_S’, the dotted neighboring word lines WL_N1’ may be affected by the voltage rise of the dotted selected word line WL_S’. That is, the voltage of the dotted neighboring word lines WL_N1’ may rise under the influence of the voltage rise of the dotted selected word line WL_S’.

However, the dotted non-neighboring word lines WL_N2’ are negligibly or not affected by the voltage rise of the dotted selected word line WL_S’. The reason is that a distance from the dotted selected word line WL_S’ of the dotted non-neighboring word lines WL_N2’ is greater than a distance from the dotted selected word line WL_S’ of the dotted neighboring word lines WL_N1’. Therefore, the voltage of the dotted non-neighboring word lines WL_N2’ do not rise but drop, and there is negligible or no occurrence of a disturbance phenomenon.

Referring to FIGS. 5B and 6B, the portions represented by the solid lines in the equalizing voltage application period Peq from the fourth time point tt4 to the fifth time point tt5 are described first.

The solid selected word line WL_S and the solid neighboring word lines WL_N1 in FIG. 5B mean a case where an equalizing voltage is applied to the solid selected word line WL_S during the equalizing voltage application period Peq and at the same time, the solid neighboring word lines WL_N1 are electrically connected to the solid selected word line WL_S, and an electric charge of the solid neighboring word lines WL_N1 is provided to the solid selected word line WL_S. During the equalizing voltage application period Peq, the voltage of the solid selected word line WL_S may rise more quickly than the voltage of the dotted selected word line WL_S’.

Because the first equalizing voltage Veq1 lower than the voltage of the solid neighboring word lines WL_N1 is applied to the solid neighboring word lines WL_N1, the voltage of the solid neighboring word lines WL_N1 is discharged and lowered. The voltage may rise in part due to the voltage rise of the solid selected word line WL_S. However, because the electric charge of the solid neighboring word lines WL_N1 is provided to the solid selected word line WL_S, the degree of voltage rise of the solid neighboring word lines WL_N1 in the equalizing voltage application period Peq is less than the degree of voltage rise of the dotted neighboring word lines WL_N1’.

Therefore, during the equalizing voltage application period, when the circuit operates in the manner as shown in FIG. 6B, the influence of the voltage rise of the solid selected word line WL_S on the voltage rise of the solid neighboring word lines WL_N1 and the resulting disturbance phenomenon may be mitigated compared to the case where the circuit operates in the manner as shown in FIG. 6A.

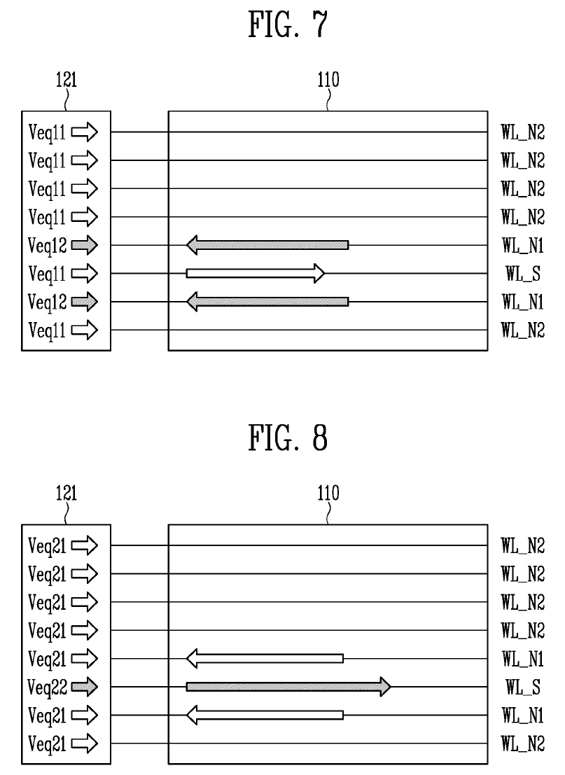

FIG. 7 is a circuit diagram illustrating an operation of a circuit of the memory device 100 during the equalizing voltage application period Peq according to a first embodiment of the present disclosure.

Referring to FIGS. 5B and 7, in the portions represented by the dotted lines in the equalizing voltage application period Peq, the row decoder 121 (of FIG. 3) applies an 11th equalizing voltage Veq11 to the selected word line WL_S and the non-neighboring word lines WL_N2, and applies a 12th equalizing voltage Veq12 to the neighboring word lines WL_N1. The 12th equalizing voltage Veq12 is lower than the 11th equalizing voltage Veq11.

When the 11th equalizing voltage Veq11 is applied to the selected word line WL_S during the equalizing voltage application period Peq, the voltage of the selected word line WL_S rises by the 11th equalizing voltage Veq11. The only rising factor of the voltage of the selected word line WL_S is the application of the 11th equalizing voltage Veq11 applied by the low decoder 121 (of FIG. 3).

The 12th equalizing voltage Veq12 is applied to the neighboring word lines WL_N1 during the equalizing voltage application period Peq. The 12th equalizing voltage Veq12 is less than the 11th equalizing voltage Veq11. When the 12th equalizing voltage Veq12 starts to be applied, the voltage of the neighboring word lines WL_N1 is higher than the 12th equalizing voltage Veq12. Therefore, when the 12th equalizing voltage Veq12 is applied, the voltage of the neighboring word lines WL_N1 is discharged and falls. However, the neighboring word lines WL_N1 are arranged adjacent to the selected word line WL_S at a position close to the selected word line WL_S, resulting in coupling between the neighboring word line WL_N1 and the selected word line WL_S. Therefore, the voltage of the neighboring word lines WL_N1 may rise under the influence of the voltage rise of the selected word line WL_S.

In this embodiment, the row decoder 121 (of FIG. 3) applies the 12th equalizing voltage Veq12, which is lower than the 11th equalizing voltage Veq11, to the neighboring word lines WL_N1 in consideration of the coupling effect between the neighboring word line WL_N1 and the selected word line WL_S. Therefore, the voltage rise of the neighboring word lines WL_N1 due to the voltage rise of the selected word line WL_S may be partially offset by the 12th equalizing voltage Veq12 which is lower than the 11th equalizing voltage Veq11. Therefore, the disturbance phenomenon may be reduced and thus the reliability of the memory device may be improved.

The 11th equalizing voltage Veq11 is applied to the non-neighboring word lines WL_N2 in the equalizing voltage application period Peq. The voltage of the non-neighboring word lines WL_N2 is higher than the 11th equalizing voltage Veq11 in the equalizing voltage application period Peq. Therefore, when the 11th equalizing voltage Veq11 is applied to the non-neighboring word lines WL_N2, the voltage of the non-neighboring word lines WL_N2 is discharged and falls. The non-neighboring word lines WL_N2 are far from the selected word line WL_S, and thus are negligibly or not affected by the voltage rise of the selected word line WL_S.

FIG. 8 is a circuit diagram illustrating an operation of a circuit of the memory device 100 during the equalizing voltage application period Peq according to a second embodiment of the present disclosure.

Referring to FIGS. 5B and 8, in the portions represented by the dotted lines in the equalizing voltage application period Peq, the row decoder 121 (of FIG. 3) applies a 22nd equalizing voltage Veq22 to the selected word line WL_S, and applies a 21st equalizing voltage Veq21 to the neighboring word lines WL_N1 and the non-neighboring word lines WL_N2. The 22nd equalizing voltage Veq22 is higher than the 21st equalizing voltage Veq21.

The 22nd equalizing voltage Veq22 is applied to the selected word line WL_S in the equalizing voltage application period Peq. Because the voltage of the selected word line WL_S is lower than the 22nd equalizing voltage Veq22 in the equalizing voltage application period Peq, the voltage of the selected word line WL_S may rise by the 22nd equalizing voltage Veq22. The only rising factor of the voltage of the selected word line WL_S is the application of the 22nd equalizing voltage Veq22.

The 21st equalizing voltage Veq21 is applied to the neighboring word lines WL_N1 in the equalizing voltage application period Peq. The 21st equalizing voltage Veq21 is lower than the 22nd equalizing voltage Veq22.

When the 21st equalizing voltage Veq21 begins to be applied to the neighboring word lines WL_N1, the voltage of the neighboring word lines WL_N1 is higher than the 21st equalizing voltage Veq21. Therefore, when the 21st equalizing voltage Veq21 is applied to the neighboring word lines WL_N1, the voltage of the neighboring word lines WL_N1 is discharged and falls, but it may rise under the influence of the voltage rise of the selected word line WL_S adjacent thereto. On the other hand, by applying the 22nd equalizing voltage Veq22, which is higher than the 21st equalizing voltage Veq21, to the selected word line WL_S, the equalizing voltage application period Peq may be shortened. Therefore, the time period during which the neighboring word lines WL_N1 are affected by the voltage rise of the selected word line WL_S is shortened, so that the disturbance phenomenon is mitigated and the reliability of the memory device may be improved.

The 21st equalizing voltage Veq21 is applied to the non-neighboring word lines WL_N2 in the equalizing voltage application period Peq. The voltage of the non-neighboring word lines WL_N2 is higher than the 21st equalizing voltage Veq21 in the equalizing voltage application period Peq. Therefore, when the 21st equalizing voltage Veq21 is applied to the non-neighboring word lines WL_N2, the voltage of the non-neighboring word lines WL_N2 is discharged and falls. Because the non-neighboring word lines WL_N2 are far from the selected word line WL_S, the non-neighboring word lines WL_N2 are negligibly or not affected by the voltage rise of the selected word line WL_S.

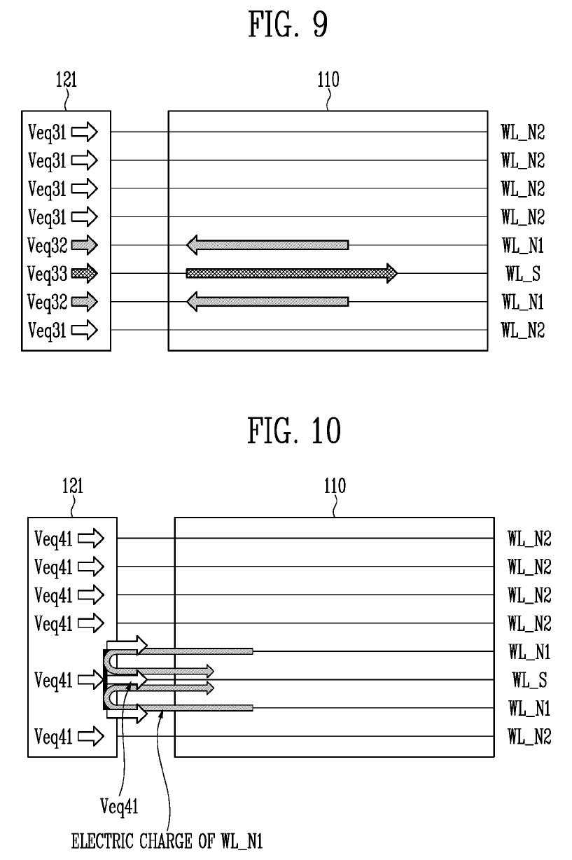

FIG. 9 is a circuit diagram illustrating an operation of a circuit of the memory device 100 during the equalizing voltage application period Peq according to a third embodiment of the present disclosure.

Referring to FIGS. 5B and 9, in the portions represented by the dotted lines in the equalizing voltage application period Peq, the row decoder 121 (of FIG. 3) applies a 33rd equalizing voltage Veq33 to the selected word line WL_S, applies a 32nd equalizing voltage Veq32 to the neighboring word lines WL_N1, and applies a 31st equalizing voltage Veq31 to the non-neighboring word lines WL_N2. The 33rd equalizing voltage Veq33 may be higher than the 31st equalizing voltage Veq31, and the 31st equalizing voltage Veq31 may be higher than the 32nd equalizing voltage Veq32.

The 33rd equalizing voltage Veq33 is applied to the selected word line WL_S in the equalizing voltage application period Peq. The voltage of the selected word line WL_S is lower than the 33rd equalizing voltage Veq33. Therefore, when the 33rd equalizing voltage Veq33 is applied to the selected word line WL_S, the voltage of the selected word line WL_S rises. The rising factor of the voltage of the selected word line WL_S is the application of the 33rd equalizing voltage Veq33.

During the equalizing voltage application period Peq, the 32nd equalizing voltage Veq32 is applied to the neighboring word lines WL_N1. The 32nd equalizing voltage Veq32 is smaller than the 31st equalizing voltage Veq31 applied to the non-neighboring word lines WL_N2 and the 33rd equalizing voltage Veq33 applied to the selected word line WL_S. When the 32nd equalizing voltage Veq32 is started to be applied to the neighboring word lines WL_N1, the voltage of the neighboring word lines WL_N1 is higher than the 32nd equalizing voltage Veq32. Therefore, when the 32nd equalizing voltage Veq32 is applied to the neighboring word lines WL_N1, the voltage of the neighboring word lines WL_N1 is discharged and lowered. Due to the coupling between the neighboring word line WL_N1 and the selected word line WL_S, the voltage of the neighboring word lines WL_N1 may rise under the influence of the voltage rise of the selected word line WL_S.

In this embodiment, the row decoder 121 (of FIG. 3) applies the 33rd equalizing voltage Veq33, which is the relatively highest voltage, to the selected word line WL_S, to shorten the equalizing voltage application period Peq, and applies the 32nd equalizing voltage Veq32, which is smaller than the 33rd equalizing voltage Veq33 applied to the selected word line WL_S and the 31st equalizing voltage Veq31 applied to the non-neighboring word lines WL_N2, to partially offset the influence of the voltage rise due to the coupling effect with the selected word line WL_S to mitigate the disturbance phenomenon.

The 31st equalizing voltage Veq31 is applied to the non-neighboring word lines WL_N2 in the equalizing voltage application period Peq. The voltage of the non-neighboring word lines WL_N2 is higher than the 31st equalizing voltage Veq31 in the equalizing voltage application period Peq. Therefore, when the 31st equalizing voltage Veq31 is applied to the non-neighboring word lines WL_N2, the voltage of the non-neighboring word lines WL_N2 is discharged and lowered. The non-neighboring word lines WL_N2 are far from the selected word line WL_S, and thus are negligibly or not affected by the voltage rise of the selected word line WL_S. Therefore, the voltage of the non-neighboring word lines WL_N2 decreases due to the application of the 31st equalizing voltage Veq31 regardless of the influence of the voltage rise of the selected word line WL_S.

FIG. 10 is a circuit diagram illustrating an operation of a circuit of the memory device 100 during the equalizing voltage application period Peq according to a fourth embodiment of the present disclosure.

Referring to FIGS. 5B and 10, the row decoder 121 (of FIG. 3) applies a 41st equalizing voltage Veq41 to the selected word line WL_S, the neighboring word lines WL_N1, and the non-neighboring word lines WL_N2. Unlike embodiments described above, in this fourth embodiment, in the equalizing voltage application period Peq, the selected word line WL_S and the neighboring word lines WL_N1 are electrically connected to each other by the row decoder 121 (of FIG. 3).

The 41st equalizing voltage Veq41 is applied to the selected word line WL_S in the equalizing voltage application period Peq. The voltage of the selected word line WL_S is lower than the 41st equalizing voltage Veq41 in the equalizing voltage application period Peq. Therefore, when the 41st equalizing voltage Veq41 is applied to the selected word line WL_S, the voltage of the selected word line WL_S rises.

During the equalizing voltage application period Peq, the voltage of the neighboring word lines WL_N1 is higher than the voltage of the selected word line WL_S and the 41st equalizing voltage Veq41. In the equalizing voltage application period Peq, the row decoder 121 (of FIG. 3) applies the 41st equalizing voltage Veq41 to the neighboring word lines WL_N1. The row decoder 121 (of FIG. 3) electrically connects the neighboring word lines WL_N1 and the selected word line WL_S. When the neighboring word lines WL_N1 are connected to the selected word line WL_S, the electric charge of the neighboring word lines WL_N1 with the high voltage is transferred to the selected word line WL_S. That is, the rising factor of the voltage of the selected word line WL_S in the equalizing voltage application period Peq is the application of the 41st equalizing voltage Veq41 and the electric charge provided from the neighboring word lines WL_N1.

Due to the application of the 41st equalizing voltage Veq41 and the inflow of the electric charge of the neighboring word lines WL_N1, the voltage of the selected word line WL_S may rise more quickly than the voltage of the selected word line WL_S which rises due to the application of the 41st equalizing voltage Veq41. Therefore, the voltage of the selected word line WL_S may be quickly stabilized.

During the equalizing voltage application period Peq, the 41st equalizing voltage Veq41 is applied to the neighboring word lines WL_N1 and the neighboring word lines WL_N1 and the selected word line WL_S are electrically connected. At the start of the equalizing voltage application period Peq, the voltage of the neighboring word lines WL_N1 is higher than the 41st equalizing voltage Veq41 and higher than the voltage of the selected word line WL_S. Therefore, during the equalizing voltage application period Peq, the neighboring word lines WL_N1 directly provide the electric charge to the selected word line WL_S, so that the voltage of the neighboring word lines WL_N1 is lowered. Therefore, because the neighboring word lines WL_N1 are electrically connected to the selected word line WL_S to lose the electric charge, the influence of the voltage rise of the selected word line WL_S may be reduced. That is, because the influence of the voltage rise of the selected word line WL_S on the neighboring word lines WL_N1 is reduced, the occurrence of the disturbance phenomenon is reduced, thereby improving the reliability of the memory device.

The 41st equalizing voltage Veq41 is applied to the non-neighboring word lines WL_N2 in the equalizing voltage application period Peq. When the 41st equalizing voltage Veq41 is started to be applied to the non-neighboring word lines WL_N2, the voltage of the non-neighboring word lines WL_N2 is higher than the 41st equalizing voltage Veq41. Therefore, when the 41st equalizing voltage Veq41 is applied to the non-neighboring word lines WL_N2, the voltage of the non-neighboring word lines WL_N2 is discharged and lowered. The non-neighboring word lines WL_N2 are far from the selected word line WL_S, and thus are negligibly or not affected by the voltage rise of the selected word line WL_S.

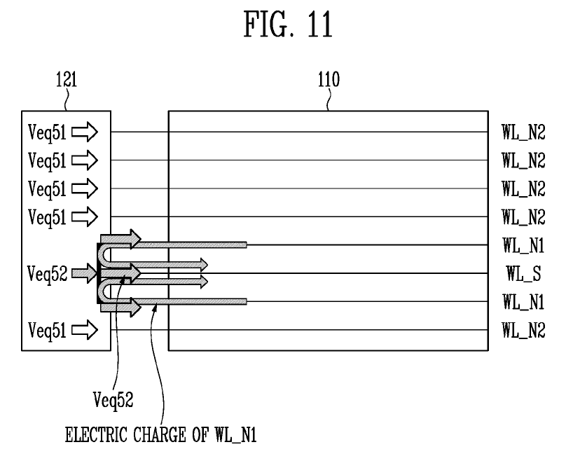

FIG. 11 is a circuit diagram illustrating an operation of a circuit of the memory device 100 during the equalizing voltage application period Peq according to a fifth embodiment of the present disclosure.

Referring to FIGS. 5B and 11, in the portions represented by the solid lines in the equalizing voltage application period Peq, the row decoder 121 (of FIG. 3) applies a 52nd equalizing voltage Veq52 to the selected word line WL_S and the neighboring word lines WL_N1, and applies a 51st equalizing voltage Veq51 to the non-neighboring word lines WL_N2. The magnitude of the 52nd equalizing voltage Veq52 may be different from the magnitude of the 51st equalizing voltage Veq51. For example, the 51st equalizing voltage Veq51 may have the magnitude smaller than the magnitude of the 52nd equalizing voltage Veq52.

In the equalizing voltage application period Peq, the 52nd equalizing voltage Veq52 is applied to the selected word line WL_S. The voltage of the selected word line WL_S has the magnitude smaller than that of each of the 51st equalizing voltage Veq51 and the 52nd equalizing voltage Veq52. Therefore, when the 52nd equalizing voltage Veq52 is applied to the selected word line WL_S, the voltage of the selected word line WL_S rises.

In the equalizing voltage application period Peq, the voltage of the neighboring word lines WL_N1 is higher than the voltage of the selected word line WL_S. Further, in the equalizing voltage application period Peq, the row decoder 121 (of FIG. 3) electrically connects the neighboring word lines WL_N1 and the selected word line WL_S. Therefore, the electric charge of the neighboring word lines WL_N1 having a high voltage may be provided to the selected word line WL_S. That is, the rising factor of the voltage of the selected word line WL_S in the equalizing voltage application period Peq is not only the application of the 52nd equalizing voltage Veq52, but also the inflow of the electric charge of the neighboring word lines WL_N1.

Due to the application of the 52nd equalizing voltage Veq52 and the inflow of the electric charge of the neighboring word lines WL_N1, the voltage of the selected word line WL_S may rise more quickly than the voltage of the selected word line WL_S which rises due to the application of the 52nd equalizing voltage Veq52. Therefore, the voltage of the selected word line WL_S may be quickly stabilized.

The 52nd equalizing voltage Veq52 is applied to the neighboring word lines WL_N1 in the equalizing voltage application period Peq, and the neighboring word lines WL_N1 are electrically connected to the selected word line WL_S. The voltage of the neighboring word lines WL_N1 is higher than the 52nd equalizing voltage Veq52 in the equalizing voltage application period Peq. In the equalizing voltage application period Peq, the voltage of the neighboring word lines WL_N1 is higher than the voltage of the selected word line WL_S.

Therefore, during the equalizing voltage application period Peq, the voltage of the neighboring word lines WL_N1 might not only be lowered as the electric charge thereof is provided to the selected word line WL_S, but it may also be discharged and lowered by the application of the 52nd equalizing voltage Veq52. In particular, because the neighboring word lines WL_N1 are electrically connected to the selected word line WL_S to directly lose the electric charge, the influence of the voltage rise of the selected word line WL_S is reduced. That is, during the equalizing voltage application period Peq, because the influence of the voltage rise of the selected word line WL_S on the neighboring word lines WL_N1 is reduced, the occurrence of the disturbance phenomenon is reduced, and the reliability of the memory device may be improved.

The 51st equalizing voltage Veq51 is applied to the non-neighboring word lines WL_N2 in the equalizing voltage application period Peq. When the 51st equalizing voltage Veq51 is started to be applied to the non-neighboring word lines WL_N2, the voltage of the non-neighboring word lines WL_N2 is higher than the 51st equalizing voltage Veq51 and the 52nd equalizing voltage Veq52. Therefore, when the 51st equalizing voltage Veq51 is applied to the non-neighboring word lines WL_N2, the voltage of the non-neighboring word lines WL_N2 is discharged and lowered. The non-neighboring word lines WL_N2 are far from the selected word line WL_S, and thus are negligibly or not affected by the voltage rise of the selected word line WL_S.

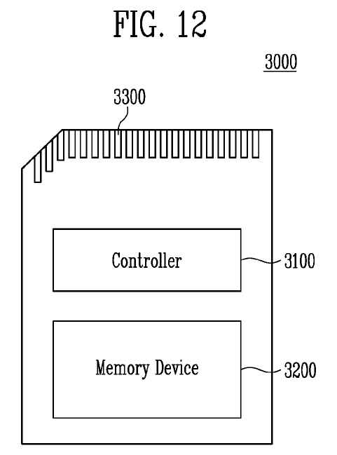

FIG. 12 is a diagram illustrating a memory card system 3000 to which a memory device 3200 according to an embodiment of the present disclosure is applied.

Referring to FIG. 12, the memory card system 3000 includes a controller 3100, the memory device 3200, and a connector 3300.

The controller 3100 is connected to the memory device 3200. The controller 3100 is configured to access the memory device 3200. For example, the controller 3100 may be configured to control a program, read, or erase operation of the memory device 3200, or to control background operations. The controller 3100 is configured to provide an interface between the memory device 3200 and a host. The controller 3100 is configured to run firmware for controlling the memory device 3200. For example, the controller 3100 may include components, such as a Random-Access Memory (RAM), a processing unit, a host interface, a memory interface, and an error correction unit.

The controller 3100 may communicate with an external device through the connector 3300. The controller 3100 may communicate with an external device (e.g., a host) based on a specific communication protocol. For example, the controller 3100 may communicate with an external device through at least one of various communication protocols, such as a Universal Serial Bus (USB), a Multi-Media Card (MMC), an embedded MMC (eMMC), a Peripheral Component Interconnect (PCI), PCI express (PCIe), Advanced Technology Attachment (ATA), Serial-ATA (SATA), Parallel-ATA (PATA), a Small Computer System Interface (SCSI), an Enhanced Small Disk Interface (ESDI), Integrated Drive Electronics (IDE), Firewire, Universal Flash Storage (UFS), Wi-Fi, Bluetooth, and non-volatile memory express (NVMe). For example, the connector 3300 may be defined by at least one of the various communication protocols described above.

The memory device 3200 may include memory cells and may be configured the same as the memory device 100 shown in FIG. 1. For example, the memory device 3200 may include the row decoder 121 (of FIG. 1). Therefore, the memory device 3200 may be configured to perform at least one of the operations of the circuit according to the first to fifth embodiments described above.

The controller 3100 and the memory device 3200 may be integrated into one semiconductor device to form a memory card. For example, the controller 3100 and the memory device 3200 may be integrated into one semiconductor device to form a memory card, such as a Personal Computer Memory Card International Association (PCMCIA), a Compact Flash (CF) card, a smart media card (SM, SMC), a memory stick, a multimedia card (MMC, RS-MMC, MMCmicro), an SD card (SD, miniSD, microSD, SDHC), Universal Flash Storage (UFS), or the like.

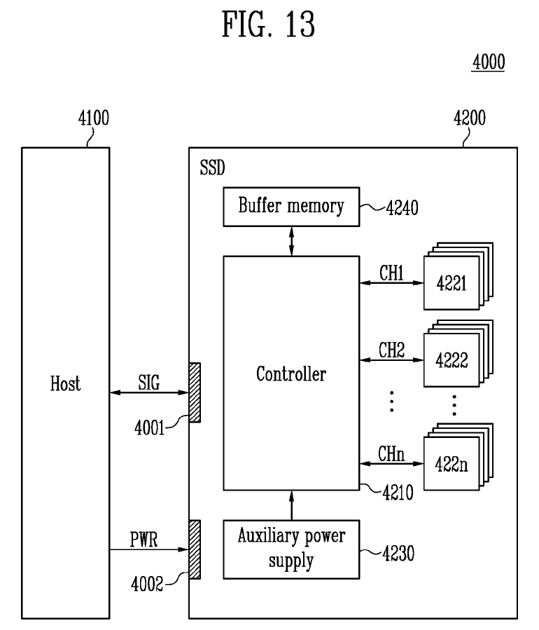

FIG. 13 is a diagram illustrating a Solid-State Drive (SSD) system 4000 to which a memory device according to an embodiment of the present disclosure is applied.

Referring to FIG. 13, the SSD system 4000 includes a host 4100 and an SSD 4200. The SSD 4200 exchanges signals SIG with the host 4100 through a signal connector 4001, and it receives power PWR through a power connector 4002. The SSD 4200 includes a controller 4210, a plurality of memory devices 4221 to 422n, an auxiliary power supply 4230, and buffer memory 4240.

The controller 4210 may control the plurality of memory devices 4221 to 422n in response to a signal received from the host 4100. For example, the signal may be signals based on an interface of the host 4100 and the SSD 4200. For example, the signal may be based on an interface of the host 4100 and the SSD 4200. For example, the signal may be defined by at least one of communication standards or interfaces, such as Universal Serial Bus (USB), multimedia card (MMC), embedded MMC (eMMC), peripheral component interconnect (PCI), PCI-express (PCI-e or PCIe), Advanced Technology Attachment (ATA), Serial-ATA, Parallel-ATA, small computer system interface (SCSI), enhanced small disk interface (ESDI), Integrated Drive Electronics (IDE), Firewire, Universal Flash Storage (UFS), Wi-Fi, Bluetooth, or NVMe standards or interfaces.

The plurality of memory devices 4221 to 422n may include cells capable of storing data. Each of the plurality of memory devices 4221 to 422n may be configured in the same manner as the memory device 100 illustrated in FIG. 1. For example, each of the plurality of memory devices 4221 to 422n may include the row decoder 121 (of FIG. 1). Therefore, each of the plurality of memory devices 4221 to 422n may be configured to perform at least one of the operations of the circuit according to the first to fifth embodiments described above.

The auxiliary power supply 4230 is connected to the host 4100 through the power connector 4002. The auxiliary power supply 4230 may receive a power voltage from the host 4100 and may be charged. The auxiliary power supply 4230 may provide the power voltage of the SSD 4200 when the power supply from the host 4100 is not smooth. For example, the auxiliary power supply 4230 may be located in the SSD 4200 or may be located outside the SSD 4200. For example, the auxiliary power supply 4230 may be located on a main board and may provide auxiliary power to the SSD 4200.

The buffer memory 4240 operates as buffer memory of the SSD 4200. For example, the buffer memory 4240 may temporarily store data received from the host 4100 or data received from the plurality of memory devices 4221 to 422n, or may temporarily store metadata (e.g., a mapping table) of the memory devices 4221 to 422n. The buffer memory 4240 may include volatile memory, such as DRAM, SDRAM, DDR SDRAM, or LPDDR SDRAM, or non-volatile memory such as FRAM, ReRAM, STT-MRAM, or PRAM.

According to some embodiments of the present disclosure, the reliability of a memory device may be improved by preventing or mitigating a disturbance due to the influence of a voltage change between word lines adjacent to each other during equalization in a read operation of the memory device.

What is claimed is:

1. A memory device, comprising:
a plurality of word lines connected to a plurality of memory cells; and
a peripheral circuit configured to sequentially perform a pass voltage application operation, a sensing voltage application operation, and an equalizing voltage application operation on the plurality of word lines,
wherein the peripheral circuit is configured to provide to a selected word line, during the equalizing voltage application operation, an electric charge of an unselected neighboring word line adjacent to the selected word line.

2. The memory device of claim 1, wherein the peripheral circuit is configured to electrically connect the selected word line and the neighboring word line during the equalizing voltage application operation.

3. The memory device of claim 1, wherein the peripheral circuit is configured to apply a first equalizing voltage to the selected word line and the neighboring word line during the equalizing voltage application operation.

4. The memory device of claim 3, wherein the first equalizing voltage is provided from one first regulator.

5. The memory device of claim 3, wherein the peripheral circuit is configured to apply a second equalizing voltage different from the first equalizing voltage to a non-neighboring word line which is not adjacent to the selected word line among the plurality of word lines.

6. The memory device of claim 5, wherein the second equalizing voltage is less than the first equalizing voltage.

7. The memory device of claim 6, wherein, during the equalizing voltage application operation, a voltage of the selected word line is lower than the first and second equalizing voltages, and a voltage of each of the neighboring word line and the non-neighboring word line is higher than the first and second equalizing voltages.

8. The memory device of claim 4, further comprising control logic configured to control the peripheral circuit,
wherein the control logic comprises:
an address setting unit configured to set an address of the neighboring word line based on an address of the selected word line; and
a regulator controller configured to control the first regulator to supply the first equalizing voltage to the selected word line and the neighboring word line based on the addresses of the selected word line and the neighboring word line during the equalizing voltage application operation.

9. A method of operating a memory device, the method comprising:
applying a pass voltage to a plurality of word lines connected to a plurality of memory cells;
applying a sensing voltage to the plurality of word lines; and
applying an equalizing voltage to the plurality of word lines,
wherein, in applying the equalizing voltage, an electric charge of an unselected neighboring word line adjacent to a selected word line is provided to the selected word line.

10. The method of claim 9, wherein, in applying the equalizing voltage, the selected word line is electrically connected to the neighboring word line.

11. The method of claim 10, wherein, in applying the equalizing voltage, a first equalizing voltage is applied to the selected word line and the neighboring word line.

12. The method of claim 11, wherein the first equalizing voltage is provided from one first regulator.

13. The method of claim 12, wherein, in applying the equalizing voltage, at least one second regulator applies a second equalizing voltage to an unselected non-neighboring word line of the plurality of word lines except for the selected word line and the neighboring word line.

14. The method of claim 13, wherein, in applying the equalizing voltage, the first equalizing voltage and the second equalizing voltage are set differently from each other.

15. The method of claim 13, wherein, in applying the equalizing voltage, the first equalizing voltage is lower than a voltage of the neighboring word line and higher than a voltage of the selected word line.

16. The method of claim 13, wherein, in applying the equalizing voltage, the first equalizing voltage is higher than the second equalizing voltage.

17. The method of claim 12, wherein applying the equalizing voltage comprises:
setting an address of the neighboring word line based on an address of the selected word line; and
controlling the first regulator to supply the first equalizing voltage to the selected word line and the neighboring word line based on the addresses of the selected word line and the neighboring word line.

18. The method of claim 17, wherein, in applying the equalizing voltage, the address of the neighboring word line is set to a plurality of addresses.
